(19) United States
(12) Patent Application Publication
(10) Pub. No.: US 2012/0300423 A1
(43) Pub. Date: Nov. 29, 2012

(54) INTERCONNECT FORMATION UNDER LOAD

(75) Inventors: Gerald G. Advocate, JR., Pleasant Valley, NY (US); Mitchell G. Ferrill, Little Meadows, PA (US); Michael J. Fisher, Poughkeepsie, NY (US); Matthew S. Kelly, Ontario (CA); Theron L. Lewis, Rochester, MN (US)

(73) Assignee: INTERNATIONAL BUSINESS MACHINES CORPORATION, Armonk, NY (US)

(21) Appl. No.: 13/116,776

(22) Filed: May 26, 2011

(51) Int. Cl. H05K 7/02; H05K 3/30

(52) U.S. Cl. 361/760; 29/842

(57) ABSTRACT

An apparatus is provided and includes a substrate, a connector, including discrete elements, each discrete element having a first end tied to a compliant spine and an opposite second end including a lead and a fastener, which is disposable to extend through the substrate and into the connector, the fastener and the connector being configured such that mechanical interference therebetween caused by fastener operation urges the connector toward the substrate to advance each of the leads toward respective solder positions in a common plane.

### BACKGROUND

The present invention relates to an interconnect formation and, more specifically, to a mechanical attachment for an interconnect formation under load.

In surface mount technology (SMT), primary attachment of large body connectors to solder pads of printed circuit boards (PCBs) can rely upon the use of load head fixtures. The connectors include pluralities of wafers (e.g., 120 wafers) that are arranged side-to-side in bays. The wafers each include leads that are to be electrically coupled to corresponding leads arrayed as solder pads on the printed circuit board. The load head fixtures aid in that process.

For example, during the conventional assembly process, the load head fixture is applied to a top of the connector to act as an external load that is applied downwards through the connector and toward the printed circuit board. The connector is then SMT reflowed under this load with the load head fixture in tact, which introduces a high thermal mass to the process that requires extended process time and reduces PCB and intermetallic compound robustness. After reflow, the solder joints are allowed to cool and the load head fixture is removed.

This conventional process requires that the load head fixture be well maintained and due to its mass can make optimizing the thermal reflow profile extremely challenging. A non-optimized thermal profile can result in solder joint defects and may lead to reduced solder joint reliability performance and quality.

### SUMMARY

According to one embodiment of the present invention, an apparatus is provided and includes a substrate, a connector, including discrete elements, each discrete element having a first end tied to a compliant spine and an opposite second end including a lead and a fastener, which is disposable to extend through the substrate and into the connector, the fastener and the connector being configured such that mechanical interference therebetween caused by fastener operation urges the connector toward the substrate to advance each of the leads toward respective solder positions in a common plane.

According to another embodiment of the invention, an apparatus is provided and includes a substrate, a connector, including discrete elements, each discrete element having a first end tied to a compliant spine and an opposite second end including a lead, each of the leads being disposable at respective initial positions in various non-common planes and a fastener, which is disposable to extend through the substrate and into the connector, the fastener and the connector being configured such that mechanical interference therebetween caused by fastener operation urges the connector toward the substrate to advance each of the leads toward respective solder positions in a common plane.

According to yet another embodiment of the invention, an apparatus is provided and includes a substrate on which leads are arrayed, a connector, including discrete elements, each discrete element having a first end tied to a compliant spine and an opposite second end including a lead, each of the leads to be respectively soldered to corresponding ones of the substrate leads and being disposable at respective initial positions in various non-common planes and a plurality of fasteners, which are each disposable to extend through the substrate and into the connector, the plurality of fasteners and the connector being configured such that mechanical interference therebetween caused by operation of the fasteners urges the connector toward the substrate to advance each of the leads toward respective solder positions in a common plane.

According to yet another embodiment of the invention, a method of assembling a connector to a substrate is provided, the connector including discrete elements, each having a first end tied to a compliant spine and an opposite second end including a lead. The method includes applying a force to the connector through the substrate to urge the connector toward the substrate and continuing the applying to advance each of the leads toward respective solder positions in a common plane.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a schematic side view of an apparatus for an interconnect formation in exploded form;

FIG. 2 is an enlarged schematic side view of a connector of the apparatus of FIG. 1;

FIG. 3 is an enlarged schematic side view of the apparatus of FIG. 1;

FIG. 4 is a schematic side view of the apparatus of FIG. 1 in assembled form;

FIG. 5 is a perspective view of a fastener with an elastic element; and

FIG. 6 is a perspective view of a fastener with a compliant element.

### DETAILED DESCRIPTION

The invention embodiments described below minimize residual solder joint stresses and thermal exposure applied during large body connector primary attachment surface mount technology (SMT) assembly by eliminating the use of conventional load head fixtures. More specifically, a back-side stiffening member approach may be utilized to overcome connector coplanarity issues. The invention embodiments further describe a “fixtureless” assembly process that helps to significantly improve overall solder joint reliability performance.

The invention embodiments help to minimize applied stress and thermal mass during assembly of high I/O, high thermal mass connectors. Due to large variation of (incoming supplier) connector lead coplanarity, as well as local non-planarity in large PCBs (i.e., board dish, etc.), conventional printed circuit board assembly (PCBA) processing for such complex connectors requires the use of an external load before and during surface mount technology (SMT) solder joint reflow to ensure sufficient solder joint formation. While the conventional process exhibits drawbacks, as described above, the present invention embodiments employ the use of screw torque force through the connector to apply comparable loads whereby the introduced loads do not lead to the drawbacks of the conventional process.

The embodiments described herein are applicable for high I/O (high density) SMT connectors where coplanarity variation is often very high, but it is to be understood that the principles disclosed herein may be used with many other applications and technologies.

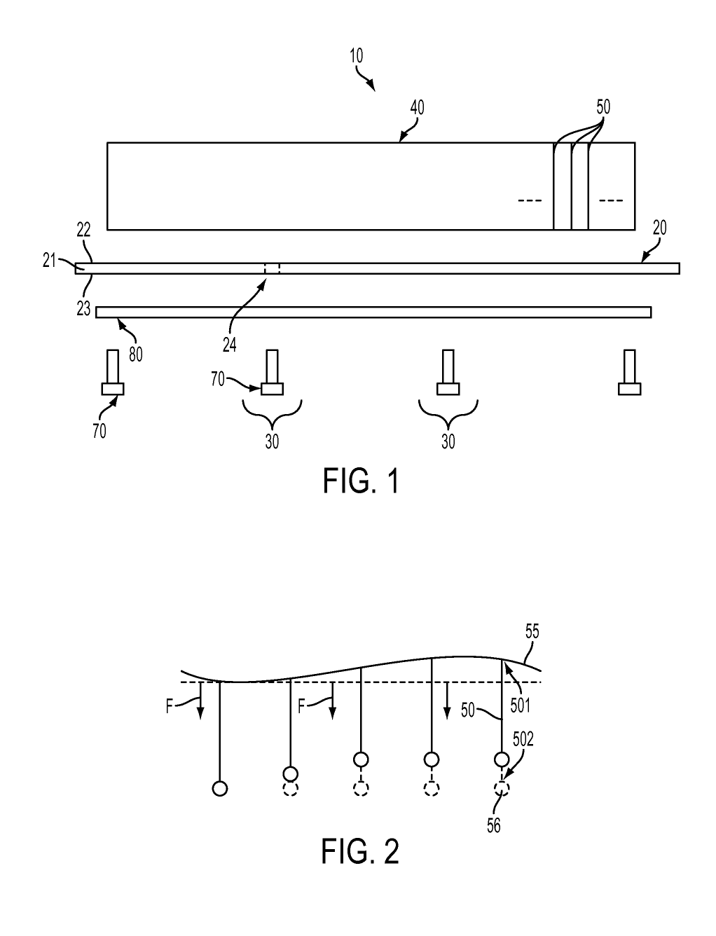

With reference to FIGS. 1-4, an apparatus 10 is provided. The apparatus 10 includes a substrate 20, such as a printed circuit board (PCB) having a body 21, an upper surface 22 and a lower surface 23. The substrate 20 is formed to define a through-hole 24 extending between the upper and lower surfaces 22, 23 through the body 21 at a fastening location 30. The upper surface 22 of the substrate 20 is further provided with leads, such as solder pads, which are arrayed thereon in a predefined configuration.

The apparatus 10 further includes a connector 40 including discrete elements 50 and a compliant spine 55. The discrete elements 50 may be provided in groups of around 120 or may be divided into sub-groups and are planar, with each discrete element 50 being arranged side-to-side with one or two adjacent discrete element(s) 50. Each of the discrete elements 50 includes a first end 501, which is tied to the compliant spine 55, and a second end 502, which is opposite the first end 501. A lead 56 is disposed on each discrete element 50 at the respective second end 502 and is to be soldered to and thereby electrically coupled to the leads arrayed as solder pads on the upper surface 22 of the substrate 20. As shown in FIG. 2, the compliance of the spine 55 positions the various leads 56 at respective initial positions at various non-common planes (see the solid lines of FIG. 2). This lack of coplanarity among the leads 56 is corrected in accordance with aspects of the invention prior to the soldering as shown in the dotted lines of FIG. 2.

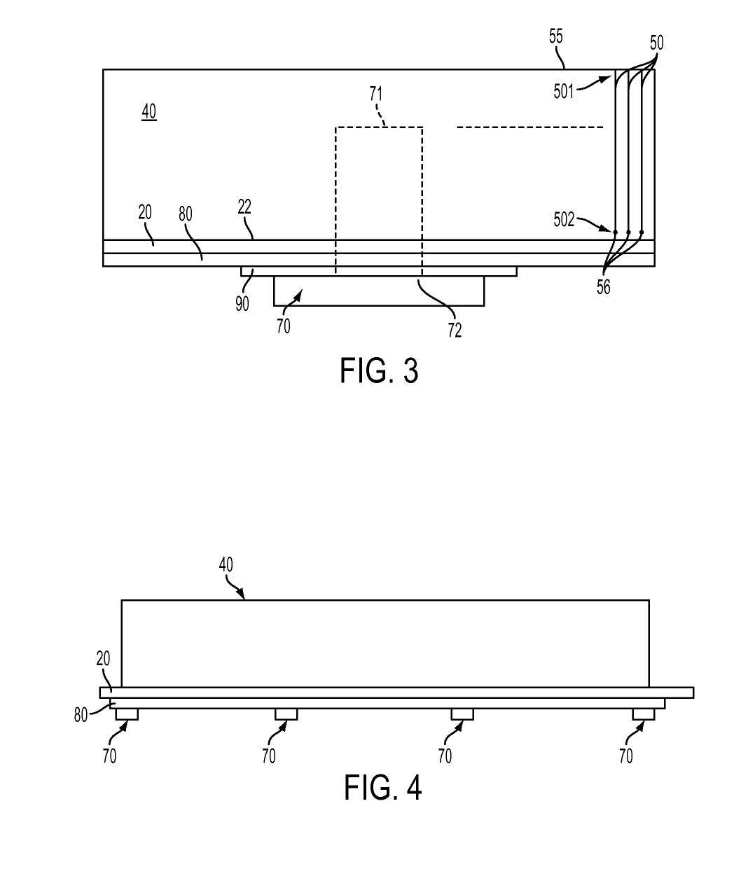

With reference to FIG. 3, the apparatus 10 further includes a fastener 70. The fastener 70 may include an elongate portion 71 and a head portion 72. The elongate portion 71 is relatively narrow and may include threading or some other surface feature thereon, which complements threading or another similar surface feature of the connector 40. The head portion 72 is relatively wide as compared to the elongate portion 71. In accordance with an embodiment of the invention, the fastener 70 may include a screw or some other similar fastening element.

The fastener 70 is disposable at the fastening location 30 with the elongate portion 71 disposed to extend through the through-hole 24 into the connector 40 such that the complementary threading (or other surface features) of the elongate portion 71 and the connector 40 mate or register with one another. The fastener 70 and the connector 40 are thus respectively configured such that mechanical interference occurring between the elongate portion 71 and the connector 40, which is caused by fastener 70 operation, causes an application of pulling force, F (see FIG. 2), to be applied to the connector 40 and, more particularly, the spine 55 from below the connector 40 and through the substrate 20. This compresses the substrate 20 between the head portion 72 and the connector 40 by urging the connector 40 toward the substrate 20. This also advances each lead 56 of each of the discrete elements 50 toward a respective solder position in a common plane, as shown in FIG. 2.

The coplanarity of the leads 56 when the leads 56 occupy the respective solder positions in the common plane permits soldering to be commenced.

Where the fastener 70 is, for example, a screw, operation of the fastener 70 may include a rotation of the fastener 70 about a longitudinal axis thereof, which extends along the elongate portion 71. This rotation causes the complementary threading (or other surface features) of the connector 40 and the elongate portion 71 to mate or register with one another, such that the head portion 72 and the connector 40 are drawn to one another. This has an effect of squeezing the substrate 20 between the relatively wide head portion 72 and the connector 40.

As such, as shown in the dotted lines of FIG. 2, the leads 56 of each of the discrete elements 50 are advanced by the application of the force, F, from the respective initial positions toward the respective solder positions relative to the upper surface 22 of the substrate 20 with a substantially decreased moment being applied to the connector 40 during or prior to, for example, reflow. In particular, coplanarity of the connector 40 with respect to the upper surface 22 of the substrate 20 is achieved with relatively high precision without introducing the additional thermal mass introduced by the load head fixture, for example. In this case, coplanarity may be defined as coplanarity between each of the leads 56 in a common plane with the common plane being substantially parallel with the upper surface 22 of the substrate.

As shown in FIGS. 3 and 4, the apparatus 10 may further include a stiffening member 80. The stiffening member 80 may be disposed between the head portion 72 and the substrate 20 and may be formed of aluminum or some other similar material having a predefined stiffness. The presence of the stiffening member 80 increases a planarity of the substrate 20 and, as a result, increases the coplanarity as defined above.

The through-hole 24, the fastening location 30 and the fastener 70 may each be each plural in number and located at plural corresponding positions. As such, the connector 40 can be pulled toward the substrate 20 at multiple locations along the planar extent of both the connector 40 and the substrate 20 and the coplanarity, as it is defined above, can be maintained during the assembly process. Further, torque can be applied to each fastener 70 simultaneously or selectively and separately such that a selective application of force can be applied to the connector 40 to thereby overcome coplanarity variations. The torque applicable to the connector 40 by way of the fastener 70 may be comparable with the compressive force that would otherwise be provided by the use of the lead head fixture of the conventional reflow process.

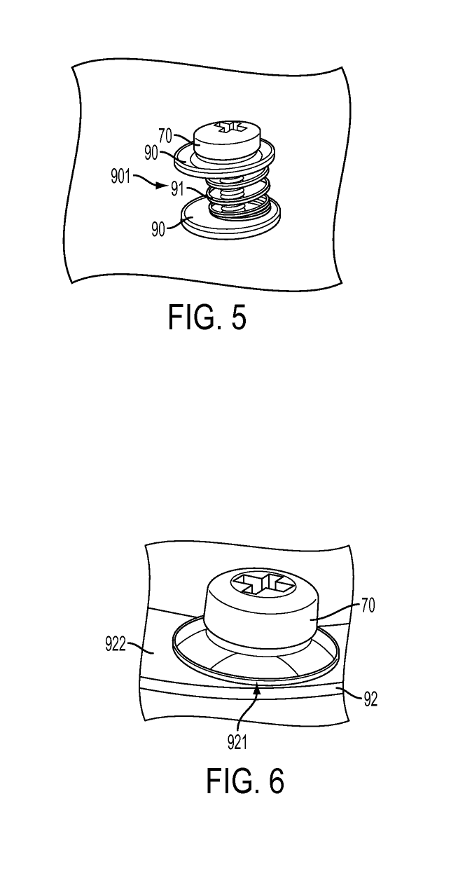

With reference to FIGS. 3, 5 and 6 and, in accordance with further embodiments, the fastener 70 may include a washer element 90 (see FIG. 3) to spread out the effective area of the head portion 72, an elastic element 91 (see FIG. 5) and/or a compliant element 92 (see FIG. 6) to prevent damage to the substrate 20. The elastic element 91 may include a spring 901 disposed between the head portion 72/washer element 90 and the substrate 20/washer element 90. The compliant element 92 may be a cupped washer element 921 and/or a compliant insulator layer 922.

Among the advantages provided by the present invention, are the selective application of force required to overcome connector coplanarity variation, improved solder joint formation and overall reliability performance, minimization of observed solder joint defects, improved alignment of leads to PCB copper pads, improved registration, minimization of thermal exposure to PCBA during processing, improved throughput during manufacturing production and improved process control and elimination of on-going load head maintenance.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The diagrams depicted herein are just one example. There may be many variations or operations described therein without departing from the spirit of the invention. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. An apparatus, comprising:
a substrate;
a connector, including discrete elements, each discrete element having a first end tied to a compliant spine and an opposite second end including a lead; and
a fastener, which is disposable to extend through the substrate and into the connector,
the fastener and the connector being configured such that mechanical interference therebetween caused by fastener operation urges the connector toward the substrate to advance each of the leads toward respective solder positions in a common plane.

2. The apparatus according to claim 1, further comprising a stiffening member disposed on the substrate.

3. The apparatus according to claim 1, wherein the substrate comprises a printed circuit board.

4. The apparatus according to claim 1, wherein the fastener comprises a screw.

5. The apparatus according to claim 1, wherein the fastener and the connector respectively comprise complementary threading.

6. The apparatus according to claim 1, wherein the fastener is plural in number.

7. The apparatus according to claim 1, wherein the fastener comprises a compliant element.

8. The apparatus according to claim 1, wherein the fastener comprises an elastic element.

9. An apparatus, comprising:
a substrate;
a connector, including discrete elements, each discrete element having a first end tied to a compliant spine and an opposite second end including a lead, each of the leads being disposable at respective initial positions in various non-common planes; and
a fastener, which is disposable to extend through the substrate and into the connector,
the fastener and the connector being configured such that mechanical interference therebetween caused by fastener operation urges the connector toward the substrate to advance each of the leads toward respective solder positions in a common plane.

10. The apparatus according to claim 9, further comprising a stiffening member disposed on the substrate.

11. The apparatus according to claim 9, wherein the substrate comprises a printed circuit board.

12. The apparatus according to claim 9, wherein the fastener comprises a screw.

13. The apparatus according to claim 9, wherein the fastener and the connector respectively comprise complementary threading.

14. The apparatus according to claim 9, wherein the fastener is plural in number.

15. The apparatus according to claim 9, wherein the fastener comprises a compliant element.

16. The apparatus according to claim 9, wherein the fastener comprises an elastic element.

17. An apparatus, comprising:
a substrate on which leads are arrayed;
a connector, including discrete elements, each discrete element having a first end tied to a compliant spine and an opposite second end including a lead, each of the leads to be respectively soldered to corresponding ones of the substrate leads and being disposable at respective initial positions in various non-common planes; and
a plurality of fasteners, which are each disposable to extend through the substrate and into the connector,
the plurality of fasteners and the connector being configured such that mechanical interference therebetween caused by operation of the fasteners urges the connector toward the substrate to advance each of the leads toward respective solder positions in a common plane.

18. A method of assembling a connector to a substrate, the connector including discrete elements, each having a first end tied to a compliant spine and an opposite second end including a lead, the method comprising:
applying a force to the connector through the substrate to urge the connector toward the substrate; and
continuing the applying to advance each of the leads toward respective solder positions in a common plane.

19. The method according to claim 18, further comprising soldering the leads to corresponding leads arrayed on the substrate.

20. The method according to claim 18, wherein the applying comprising applying the force at plural positions.
